(19) United States
(12) Patent Application Publication
(10) Pub. No.: US 2003/0132513 A1
(43) Pub. Date: Jul. 17, 2003

(54) Semiconductor package device and method

(75) Inventors: Marc Chason, Schaumburg, IL (US); Janice Danvir, Arlington Heights, IL (US); Jing Qi, Schaumburg, IL (US); Nadia Yala, Schaumburg, IL (US)

Correspondence Address: FITCH EVEN TABIN AND FLANNERY, 120 SOUTH LA SALLE STREET, SUITE 1600, CHICAGO, IL, 60603-3406, US

(73) Assignee: Motorola, Inc.

(21) Appl. No.: 10/044,777

(22) Filed: Jan. 11, 2002

(51) Int. Cl. H01L 23/02; H01L 23/22; H01L 23/24

(52) U.S. Cl. 257/678; 257/687

(57) ABSTRACT

An interposer-based semiconductor package (40) having at least one semiconductor die (21) attached to one side thereof also has, prior to placement on a printed wiring board (61), an underfill material (31) disposed at least partially thereon. Depending upon the embodiment, the underfill material (31) may initially cover interface electrodes (12) on the interposer (11). Such material (31) can be selectively removed to partially expose the interface electrodes (12). In other embodiments, apertures (101) can be left in the underfill material (31) during deposition, or formed after the underfill material (31) has been deposited, and the interface electrodes (12) subsequently formed in the apertures (101). Deposition of the underfill material (31) can be done with a single interposer-based package (40) or simultaneously with a plurality of such packages. Once deposited, the underfill material can be processed to render it relatively stable an substantially non-tacky. So processed, the package can be easily handled.

### TECHNICAL FIELD

This invention relates generally to semiconductor packages and more particularly to semiconductor packages having an interposer and interface electrodes.

### BACKGROUND

Some semiconductor packages, such as area array packages, often include a semiconductor die that is electrically and physically coupled to an interposer. The interposer will often have interface electrodes disposed on one side thereof to contact counterpart conductive surfaces on, for example, a printed wiring board. Once soldered in place, the semiconductor die can interface as desired with other elements on the printed wiring board. Chip scale packages and ball grid arrays comprise two such packages. Generally speaking, such packages function satisfactorily when installed as described.

There are, however, certain applications where performance is less than satisfactory. For example, as portable electronic devices get smaller, lighter, and use thinner printed wiring board material, this approach to packaging sometimes leads to catastrophic failure when the device is subjected to sudden shock as when dropped to a hard surface. Such failures are often the result of the physical, and hence the electrical, coupling between the printed wiring board and the interposer being broken when the corresponding substrate deflects.

Some manufacturers have attempted to remedy this problem by installing the packages on printed wiring boards as before and then underfilling the package with a liquid material that is then processed to cause the material to harden and provide additional physical integrity. While effective, this approach represents considerable undesired added complexity, manufacturing cycle time, and cost.

### BRIEF DESCRIPTION OF THE DRAWINGS

The above needs are at least partially met through provision of the semiconductor package device and method described in the following detailed description, particularly when studied in conjunction with the drawings, wherein:

FIGS. 1 and 2 illustrate a prior art interposer-based package;

FIGS. 3 and 4 illustrate a first embodiment of an interposer-based package configured in accordance with the invention;

FIG. 5 illustrates an interposer-based package as configured in accordance with the invention disposed in pick-and-place packaging;

FIGS. 6 and 7 illustrate installation of an interposer-based package as configured in accordance with the invention on a printed wiring board;

FIGS. 8 through 11 illustrate alternative embodiments for the interposer-based package as configured in accordance with the invention;

FIGS. 12 and 13 illustrate yet an additional alternative embodiment for an interposer-based package as configured in accordance with the invention;

FIG. 14 illustrates a top plan depiction of a plurality of singulated interposer-based packages as configured in accordance with the invention; and

FIG. 15 illustrates a top plan depiction of a panel comprising a plurality of interposer-based packages as configured in accordance with the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, some components may be shown in reduced number in order to render more clearly an understanding of various embodiments of the present invention.

### DETAILED DESCRIPTION

Generally speaking, pursuant to these various embodiments, an interposer having at least one semiconductor die attached to a first side thereof also has, prior to placement on a printed wiring board, an underfill material disposed at least partially thereon. Depending upon the embodiment, the underfill material may initially cover interface electrodes as may be on the interposer. In this case, the material can be selectively removed to partially expose the interface electrodes. In other embodiments, apertures can be left in the underfill material during deposition, or formed after the underfill material has been deposited, and the interface electrodes subsequently formed in the apertures. Deposition of the underfill material can be done with a single interposer-based package or simultaneously with a plurality of such packages. Once deposited, the underfill material can be processed to render it relatively stable and substantially non-tacky. So processed, the package can be easily handled. In one embodiment, the resultant packages can be placed in pick-and-place carrier packaging. These packages are then readily and conveniently handled by ordinary pick-and-place manufacturing equipment. Once placed on a printed wiring board or other substrate, additional processing (such as, for example, heating) can be used to cause the underfill material to flow as necessary to fill gaps between the interposer and the printed wiring board and to harden as appropriate to secure the interposer-based package firmly in place on the printed wiring board while permitting solder joint connections.

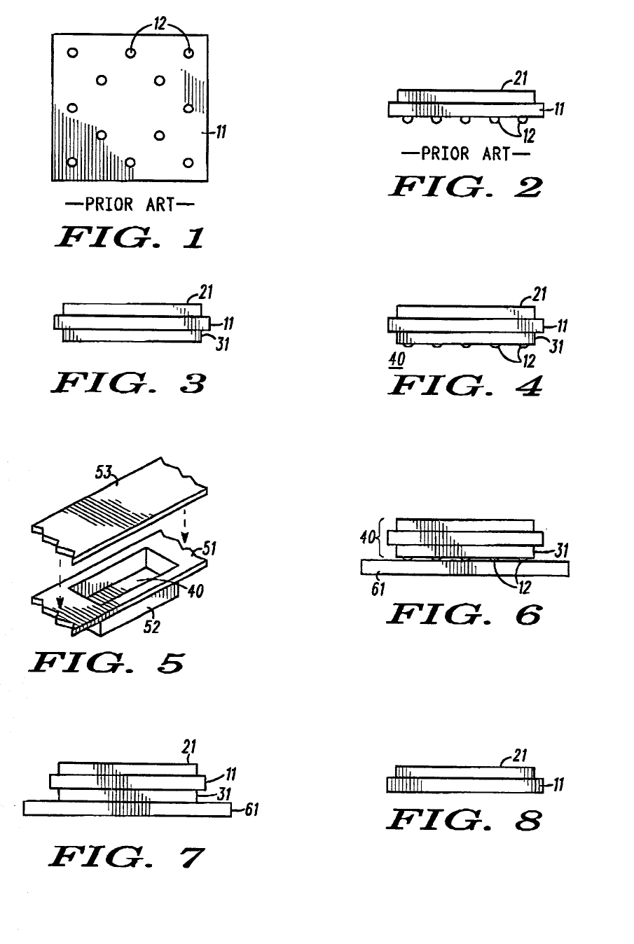

Referring now to FIGS. 1 and 2, a standard interposer-based package will typically include an interposer 11 having one or more semiconductor dies 21 disposed on one surface thereof and one or more interface electrodes 12 disposed on one surface thereof as well. The interposer 11 itself can be configured as known in the art, and consequently can include signal routing and/or passive or active circuit elements (either surface mounted or embedded within the interposer 11). Such interposers 11 can be fabricated independently of the semiconductor die 21 or can be fabricated directly in conjunction with the semiconductor die 21 as understood in the art. The semiconductor die 21 can be any such die, and can include any semiconductor material, such as, for example, silicon, gallium arsenide, and so forth. The interface electrodes 12 can be, for example, solder balls and/or solder bumps (many individuals skilled in the art use these terms virtually interchangeably) as well understood in the art, but other electrode structures could be used compatibly with these teachings as well.

Referring now to FIG. 3, and in accordance with this embodiment, a layer of material is deposited on the interposer 11 to substantially cover (or in this embodiment, fully cover) the interface electrodes 12 and thereby form underfill material 31 as will become more evident further below. The underfill material 31 can be comprised of a variety of materials, depending upon the specific intended application, including filled or unfilled thermoset or thermoplastic material, fluxing material, and so forth. The underfill material 31 can be a film or a liquid when applied and may, if desired, comprise a reworkable substance. This material 31, when a film, can be applied using known lamination techniques. This material 31, when a liquid, can be deposited in a variety of ways, including by screen printing, stencil printing, jetting, pad printing, and so forth.

As applied in these embodiments, the underfill material 31 covers the interface electrodes 12. The underfill material 31 can be selectively removed to partially expose the interface electrodes 12 as shown in FIG. 4 (of course, the material 31 should be sufficiently hardened, though not fully hardened, to facilitate some removal processing). Various processes can be used to effect this material removal including chemical mechanical polishing, abrading, grinding, mechanical polishing, and laser ablation to name a few. The underfill material 31 can then be processed with low-temperature processing, including as appropriate low-temperature drying to evaporate solvents from the material 31 and/or B-stage processing to provide limited crosslinking within the coating and/or cool the material 31 below a solidification temperature to substantially stabilize the material 31 to render it non-tacky for handling purposes though still not fully hardened.

The resultant package 40 is non-tacky and hence can be readily handled with ease prior to such placement. For example, and with reference to FIG. 5, such a package 40 can be readily placed in a variety of pick-and-place carriers, including a tape and reel carrier as shown. Such a tape and reel carrier typically includes a tape 51 formed of plastic and having small wells 52 formed therein to receive singulated components such as the package 40. A light plastic cover 53 is then placed over the tape 51 and well 52 to hold the package 40 in place during transport and handling. Other carriers are of course suitable as well, including waffle packs, matrix trays, and any other carrier that is useful for presenting a component for pick-and-place processing.

So processed, and referring now to FIG. 6, the package 40 can be placed on a printed wiring board 61 or other suitable surface. It will often be desirable to have the package 40 adhere to some extent to the printed wiring board 61 at this time. Such adherence can be achieved through a variety of known ways. If desired, the underfill material 31 itself could be comprised of a substance that is non-tacky as described above during handling and transport, but that can be made tacky through additional processing such as, for example, pre-heating. Otherwise, one can use a tacky solder flux or solder paste (as may ordinarily be applied in any event to permit subsequent soldering as understood in the art) or other applied adhesive. The underfill material 31 disposed thereon can be further processed to cause the underfill material 31 to flow and harden to aid in physically securing the package 40 in place as illustrated in FIG. 7 (of course, the appropriate electromechanical connections are also made through known soldering processes of choice). Depending upon the particular underfill material 31 or materials used in a given application, such processing will often including heating. Such heating can be imparted through an independent mechanism or can be effected through other contemporaneous processes (such as, for example, moving the printed wiring board 61 through a solder reflow process).

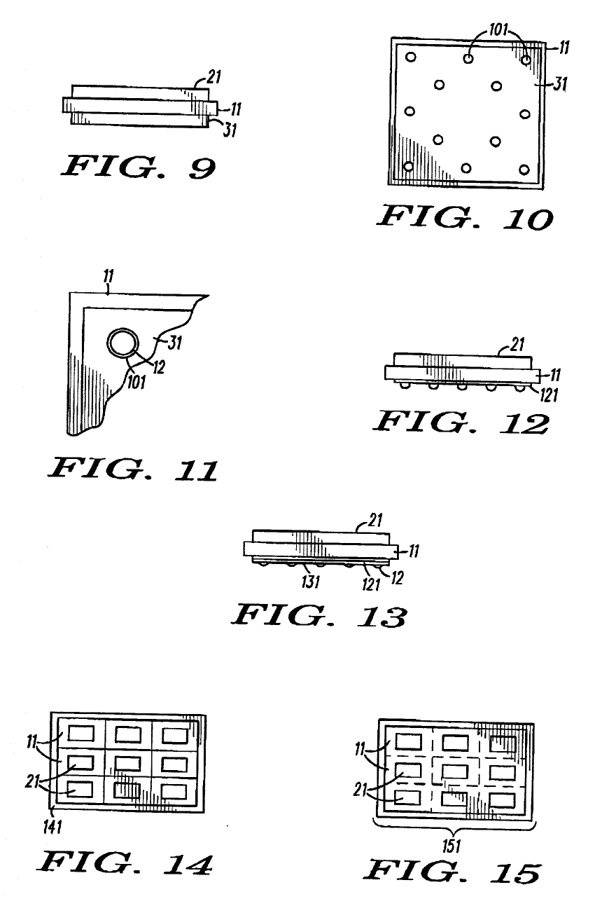

In the embodiments described above, the interface electrodes 12 are already in place before the underfill material 31 is deposited on the interposer 11. If desired, however, some or all of the interface electrodes 12 can be added after the underfill material 31 has been deposited on the interposer 11. For example, with reference to FIG. 8, an interposer 11 having an attached semiconductor die 21 can be provided that does not yet have the interface electrodes 12 attached thereto (of course, the interposer 11 will have conductive pads to which the interface electrodes 12 can eventually be attached as well understood in the art). Referring now to FIG. 9, the underfill material 31 can then be deposited on the interposer 11 as described above. In one embodiment, however, and referring now to FIG. 10, apertures 101 can be formed as the underfill material 31 is being deposited. In the alternative, the underfill material 31 can be deposited over the surface of the interposer 11 and the apertures can be subsequently formed (by use of, for example, photolithography, laser drilling, and so forth). So configured, and with reference to FIG. 11, interface electrodes 12 can then be formed within the apertures 101. For example, solder balls/bumps can be formed by depositing solder into the apertures 101 using screen printing, jetting, or the like. If the interface electrodes 12 are embedded too far within the underfill material 31, some of the underfill material 31 can be removed as described above.

In another embodiment, and referring now to FIGS. 12 and 13, the underfill material can be formed through a series of deposited layers. For example, a first layer 121 of underfill material can be deposited followed by a second layer 131 of underfill material. Typically, for most applications, it would probably be preferable to process each layer with B-stage processing prior to depositing each subsequent layer when using this approach.

As described, a single interposer-based package can be processed as described to provide a pre-placement package having an underfill material deposited thereon. If desired, a plurality of such packages can be simultaneously processed as described. For example, and referring to FIG. 14, a plurality of singulated interposer-based packages can be held substantially co-planar to one another using, for example, a simple frame 141 or other carrier and the appropriate surfaces of the packages processed as described above to deposit the underfill material. As another example, and referring to FIG. 15, a panel 151 comprised of a plurality of pre-singulation interposer-based packages can be provided and processed as described above. Following the deposition and processing of the underfill material, the packages can then be singulated from the panel 151 in accordance with well understood prior art technique to provide singulated interposer-based packages as otherwise described above.

A wide variety of materials can be used consistently with the above processes and embodiments. Furthermore, a wide range of processing parameters can be varied, including package size and constituent element sizes, to suit a wide variety of application requirements. Those skilled in the art will recognize that a wide variety of modifications, alterations, and combinations can be made with respect to the above described embodiments without departing from the spirit and scope of the invention. As one example, in the embodiments described above the semiconductor die 21 is on an opposite side of the interposer 11 from the interface electrodes 12. If desired, there could also be semiconductor dies on the same side of the interposer 11 as the interface electrodes 12 without departing from the teachings set forth above. Such modifications, alterations, and combinations are therefore to be viewed as being within the ambit of the inventive concept.

We claim:

1. A method comprising:
providing an interposer having at least one semiconductor die attached to a first side thereof;
prior to placing the interposer on a printed wiring board, disposing an underfill material on at least a portion of a second side thereof.

2. The method of claim 1 wherein providing an interposer includes providing an interposer having at least one interface electrode disposed on the second side thereof

3. The method of claim 2 wherein providing an interposer having at least one interface electrode disposed on the second side thereof includes providing an interposer having at least one interface electrode comprising one of a solder bump and a solder ball disposed on the second side thereof.

4. The method of claim 1 and further comprising adding at least one interface electrode to the second side of the interposer.

5. The method of claim 4 wherein adding at least one interface electrode to the second side of the interposer includes adding at least one interface electrode to the second side of the interposer after disposing the underfill material.

6. The method of claim 5 wherein disposing an underfill material includes disposing an underfill material on at least a portion of the second side thereof while simultaneously providing at least one aperture in the underfill material.

7. The method of claim 6 wherein adding at least one interface electrode to the second side of the interposer after disposing the underfill material includes adding at least one interface electrode in the at least one aperture.

8. The method of claim 5 and further comprising forming at least one aperture in the underfill material and wherein adding at least one interface electrode includes adding at least one interface electrode in the at least one aperture.

9. The method of claim 1 wherein disposing an underfill material includes disposing a plurality of material layers.

10. The method of claim 9 wherein disposing a plurality of material layers includes exposing at least one of the material layers to low-temperature processing.

11. The method of claim 10 wherein exposing at least one of the material layers to low-temperature drying includes exposing each of the material layers to low-temperature drying.

12. The method of claim 1 and further comprising removing at least a portion of the underfill material to expose at least a portion of at least one interface electrode.

13. The method of claim 12 wherein removing at least a portion of the underfill material includes using at least one of chemical mechanical polishing, abrading, grinding, mechanical polishing, and laser ablation to expose at least a portion of at least one interface electrode.

14. The method of claim 1 wherein providing an interposer having at least one semiconductor die attached to one side thereof includes providing a plurality of interposers disposed substantially co-planar to one another, wherein at least some of the interposers each have at least one semiconductor die attached to one side thereof.

15. The method of claim 14 wherein providing a plurality of interposers includes providing a plurality of singulated interposers.

16. The method of claim 14 wherein providing a plurality of interposers includes providing a panel comprised of a plurality of interposers.

17. The method of claim 14 wherein disposing an underfill material on at least a portion of the second side of the interposer includes disposing an underfill material on at least a portion of the second side of at least some of the plurality of interposers.

18. The method of claim 17 and further comprising, after disposing the underfill material, singulating the interposers to provide singulated interposers.

19. The method of claim 18 and further comprising placing at least some of the singulated interposers into a carrier to facilitate subsequent placement of the singulated interposers on a printed wiring board.

20. The method of claim 19 wherein placing at least some of the singulated interposers into a carrier includes placing at least some of the singulated interposers into at least one of a tape and reel carrier, a waffle pack, and a matrix tray.

21. A method comprising:
providing a printed wiring board;
providing at least one interposer having:
a first side having at least one semiconductor die affixed thereto;
a second side having:
an underfilling material disposed thereon; and
at least one interface electrode at least partially exposed through the underfilling material; and
disposing the at least one interposer on the printed wiring board.

22. The method of claim 21 wherein the at least one interface electrode comprises one of a solder ball and a solder bump.

23. The method of claim 21 and further comprising further processing the at least one interposer on the printed wiring board to at least partially harden the underfilling material.

24. The method of claim 23 wherein further processing includes heating the underfilling material.

25. A device comprising:
a pre-placement interposer having:
a first side having at least one semiconductor die affixed thereto; and
a second side having:
an underfilling material disposed thereon; and
at least one interface electrode at least partially exposed through the underfilling material.

26. The device of claim 25 wherein the interposer comprises means for physically and electrically coupling a semiconductor die to a printed wiring board.

27. The device of claim 25 wherein the underfilling material comprises adherence means for physically coupling the interposer to a printed wiring board.

28. The device of claim 25 wherein the second side has a plurality of interface electrodes at least partially exposed through the underfilling material.
